(19) United States
(12) Patent Application Publication
(10) Pub. No.: US 2026/0179886 A1
(43) Pub. Date: Jun. 25, 2026

(54) FILM FORMING METHOD AND PLASMA PROCESSING APPARATUS

(71) Applicant: Tokyo Electron Limited, Tokyo (JP)

(72) Inventors: Miyako KANEKO, Nirasaki-shi (JP); Shigehiro MIURA, Nirasaki-shi (JP); Tatsuo MATSUDO, Nirasaki-shi (JP); Takahiro SHINDO, Fuchu-shi (JP); Naoko SUZUKI, Nirasaki-shi (JP)

(21) Appl. No.: 19/545,086

(22) Filed: Feb. 20, 2026

Related U.S. Application Data
(63) Continuation of application No. PCT/JP2024/029017, filed on Aug. 15, 2024.

(30) Foreign Application Priority Data
Aug. 29, 2023 (JP) 2023-139139

(51) Int. Cl. H01J 37/32; C23C 16/26; C23C 16/458; C23C 16/48; C23C 16/52

(52) U.S. Cl. CPC H01J 37/32449; C23C 16/26; C23C 16/4583; C23C 16/48; C23C 16/52; H01J 2237/332

(57) ABSTRACT

A film forming method includes: a) placing a substrate on a stage inside a processing container, in which the stage configured to place the substrate on the stage and connected to a ground via a first electrical path is disposed, a conductive ring connected to the ground via a second electrical path is disposed around the stage, and an electrode is disposed to face the stage; and b) forming graphene on the substrate by while supplying a process gas including a carbon-containing gas into the processing container, setting an impedance of the first electrical path to be higher than an impedance of the second electrical path, and supplying power having a frequency of a very high frequency (VHF) band or lower to the electrode to generate plasma inside the processing container.

### CROSS-REFERENCE TO R ELATED APPLICATION

This application is a Bypass Continuation application of PCT International Application No. PCT/JP2024/029017, filed on Aug. 15, 2024 and designating the United States, the international application being based upon and claiming the benefit of priority from Japanese Patent Application No. 2023-139139, filed on Aug. 29, 2023, the entire contents of which is incorporated herein by reference.

### TECHNICAL FIELD

The present disclosure relates to a film forming method and a plasma processing apparatus.

### BACKGROUND

Patent Document 1 discloses a preprocessing method, which is performed before graphene growth by a chemical vapor deposition (CVD) method on a catalyst metal layer formed on a workpiece, and which includes a plasma treatment process of activating the catalyst metal layer by applying plasma of a process gas including a reducing gas and a nitrogen-containing gas to the catalyst metal layer.

### PRIOR ART DOCUMENT

### Patent Document

Patent Document 1: Japanese Patent Application Publication No. 2013-100205

### SUMMARY

A film forming method according to one embodiment of the present disclosure includes a process a) and a process b). In the process a), a substrate is placed on a stage inside a processing container, in which the stage configured to place the substrate on the stage and connected to a ground via a first electrical path is disposed, a conductive ring connected to the ground via a second electrical path is disposed around the stage, and an electrode is disposed to face the stage In the process b), graphene is formed on the substrate by while supplying a process gas including a carbon-containing gas into the processing container, setting an impedance of the first electrical path to be higher than an impedance of the second electrical path, and supplying power having a frequency of a very high frequency (VHF) band or lower to the electrode to generate plasma inside the processing container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view schematically illustrating a plasma processing apparatus according to an embodiment.

FIG. 2 is a view schematically illustrating an example of a flow of radio-frequency power according to an embodiment.

FIG. 3A is a view illustrating ion energy distributions in a first experiment.

FIG. 3B is a view illustrating ion energy distributions in the first experiment.

FIG. 4 is a flowchart illustrating an example of a film forming method according to an embodiment.

FIG. 5 is a view illustrating a Raman spectrum of a substrate on which graphene was formed in a second experiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, an embodiment of a film forming method and a plasma processing apparatus will be described in detail with reference to the drawings. Further, the disclosed film forming method and plasma processing apparatus are not limited by the following embodiment.

Conventionally, a technique has been known, for example, for introducing microwaves into a chamber to generate plasma and forming graphene on a substrate. For plasma generation, microwaves of, for example, 860 MHz are used.

In consideration of improvement in productivity of graphene film formation, a multi-wafer type film forming apparatus is required. However, it is difficult to adapt multi-wafer processing to a film forming apparatus that generates plasma by microwaves. For multi-wafer processing, a plasma processing apparatus that generates plasma by power having a frequency of a VHF band or a frequency lower than the VHF band may be used. The VHF band refers to a frequency of 30 MHz to 300 MHz.

However, plasma generated by power having a frequency of the VHF band or lower (30 MHz or lower) has high ion energy, and it has been difficult to form a continuous graphene film due to ion bombardment. Accordingly, there is a demand for a technology capable of forming graphene on a substrate even with plasma generated by power having a frequency of the VHF band or lower.

### EMBODIMENTS

### (Configuration of Plasma Processing Apparatus)

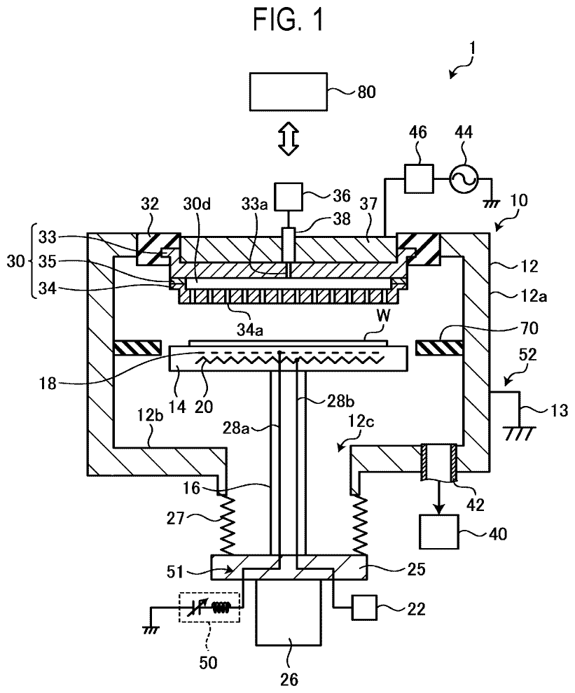

Next, embodiments will be described. FIG. 1 is a diagram schematically illustrating a plasma processing apparatus 1 according to an embodiment. The plasma processing apparatus 1 shown in FIG. 1 includes a chamber 10. The chamber 10 provides an internal space therein. The chamber 10 may include a chamber body 12. The chamber body 12 has a substantially cylindrical shape. The chamber body 12 provides walls of the chamber 10, which includes a sidewall 12a and a bottom wall 12b. The internal space of the chamber 10 is provided in the chamber body 12. The chamber body 12 is formed of a conductive metal such as aluminum. The chamber body 12 is grounded via a wiring 13. In the embodiment, the chamber 10 corresponds to a processing container of the present disclosure.

The plasma processing apparatus 1 further includes a substrate support 14. The substrate support 14 is provided inside the chamber 10. The substrate support 14 is configured to support a substrate W placed thereon. The substrate support 14 has a body. The body of the substrate support 14 is formed of, for example, aluminum nitride and may have a disk shape. In the embodiment, the substrate support 14 corresponds to a stage of the present disclosure.

The substrate support 14 is supported by a support 16. The support 16 is formed in a cylindrical shape. An opening 12c is formed in a vicinity of a center of the bottom wall 12b of the chamber 10. The substrate support 14 passes through the opening 12c and is connected to a flange 25 below the bottom wall 12b. The flange 25 is formed to be wider and flatter than the opening 12c. The flange 25 is configured to be raised and lowered by a lifting mechanism 26. As the flange 25 is raised and lowered, the support 16 and the substrate support 14 are raised and lowered along with the flange 25. By the vertical movement of the substrate support 14, a distance between the substrate W placed on the substrate support 14 and an upper electrode 30, which will be described later, is changed. The lifting mechanism 26 is controlled by a controller 80, which will be described later.

The bottom wall 12b of the chamber 10 and the flange 25 are connected via a bellows 27. As a result, airtightness within the chamber 10 is maintained even when the flange 25 is raised and lowered by the lifting mechanism 26. The substrate support 14 is electrically isolated from the chamber 10. In one embodiment, the substrate support 14 is electrically isolated from the chamber 10 by at least one of connecting the substrate support 14 and the support 16 via an insulator, or connecting the support 16 and the flange 25 via an insulator.

The substrate support 14 is configured to be raised and lowered in the chamber 10 by the lifting mechanism 26 via the flange 25 and the support 16. FIG. 1 shows a state in which the substrate support 14 is raised.

When loading and unloading the substrate W, the substrate support 14 is lowered by the lifting mechanism 26 to a transfer position at which the substrate W can be loaded and unloaded. A load/unload port (not shown) is formed in the sidewall 12a of the chamber 10 at a position substantially the same height as the transfer position. The load/unload port is configured to be opened and closed by a gate valve. The substrate W is loaded into the chamber 10 via the load/unload port (not shown) by a transfer mechanism such as a transfer arm, and is placed on the substrate support 14 which has been lowered to the transfer position.

When performing processing on the substrate W, the substrate support 14 is raised by the lifting mechanism 26. When performing a film forming process on the substrate W, a position of the substrate support 14 is adjusted to a processing position at which a distance between an upper surface of the substrate support 14 and a lower surface of the upper electrode 30 described later becomes a predetermined distance. The predetermined distance is set by film forming conditions.

The substrate support 14 includes a lower electrode 18. The lower electrode 18 is formed of a conductive metal such as aluminum and is embedded in a body of the substrate support 14. The substrate support 14 may have a heater 20. The heater 20 is embedded in the body of the substrate support 14. The heater 20 is a resistance heating element and is formed of a metal, for example, molybdenum, having a high melting point. The heater 20 is connected to a heater power supply 22 via a wiring 28b provided in the substrate support 14, the support 16, and the flange 25. The heater power supply 22 is provided outside the chamber 10. The heater 20 heats the substrate W by receiving power from the heater power supply 22 and generating heat. Further, the entire substrate support 14 may be formed of a conductive metal such as aluminum and function as the lower electrode 18. In this case, a covering is provided on the substrate support 14 to cover an upper surface and a side surface of the substrate support 14. The covering is formed of an insulating material.

The plasma processing apparatus 1 further includes a ring electrode 70. The ring electrode 70 has a flat ring shape and is formed of a conductive metal such as aluminum. The ring electrode 70 is provided inside the chamber 10 and outside a space between the lower electrode 18 and the upper electrode 30. The ring electrode 70 is provided to surround a periphery of the substrate support 14 when the substrate support 14 is raised. The ring electrode 70 is provided along the sidewall of the chamber 10 (or the chamber body 12). The ring electrode 70 is formed with an internal diameter slightly larger than an external diameter of the substrate support 14, and is disposed with a gap from a side surface of the substrate support 14 so as not to be in contact with the substrate support 14 which is being raised or lowered. A placement position of the ring electrode 70 is adjusted so that the upper surface of the substrate support 14 at the processing position and an upper surface of the ring electrode 70 are, for example, at the same height. Alternatively, the placement position of the ring electrode 70 may be adjusted so that, for example, the upper surface of the ring electrode 70 is positioned higher than the upper surface of the substrate support 14 at the processing position. Alternatively, the placement position of the ring electrode 70 may be adjusted so that, for example, the upper surface of the ring electrode 70 is positioned lower than the upper surface of the substrate support 14 at the processing position. The ring electrode 70 is connected to the sidewall 12a of the chamber body 12 and is electrically connected to the chamber body 12. The chamber body 12 is grounded via the wiring 13. An electrical path 52 through which the ring electrode 70 is connected to the ground via the chamber body 12 and the wiring 13 is formed. The electrical path 52 is constituted by the chamber body 12, which is electrically connected to the ring electrode 70, and by the wiring 13. Further, the ring electrode 70 may be a mesh-type electrode that provides a plurality of holes. Alternatively, the ring electrode 70 may be a slit-type electrode that provides a plurality of elongated holes. In the embodiment, the ring electrode 70 corresponds to a ring of the present disclosure, and the electrical path 52 corresponds to a second electrical path of the present disclosure.

The plasma processing apparatus 1 further includes the upper electrode 30. The upper electrode 30 is provided above the substrate support 14. The upper electrode 30 constitutes a ceiling of the chamber 10. The upper electrode 30 is electrically isolated from the chamber body 12. In one embodiment, the upper electrode 30 is fixed to an upper portion of the chamber body 12 via an insulator 32. In the embodiment, the upper electrode 30 corresponds to an electrode of the present disclosure.

In one embodiment, the upper electrode 30 is configured as a showerhead. The upper electrode 30 may include a base 33 and a ceiling plate 34. The upper electrode 30 may further include an intermediate member 35. The base 33, the ceiling plate 34, and the intermediate member 35 are conductive and formed of, for example, aluminum. The base 33 is provided above the ceiling plate 34. A heat insulator 37 may be provided on the base 33. The intermediate member 35 has a substantially annular shape and is held between the base 33 and the ceiling plate 34. The base 33 and the ceiling plate 34 provide a gas diffusion space 30d therebetween. The base 33 provides a gas introduction port 33a connected to the gas diffusion space 30d. The ceiling plate 34 provides a plurality of gas holes 34a. The plurality of gas holes 34a extends downward from the gas diffusion space 30d and penetrates the ceiling plate 34 in a thickness direction of the ceiling plate 34.

The plasma processing apparatus 1 further includes a gas supply 36. The gas supply 36 is configured to supply a gas into the chamber 10. In one embodiment, the gas supply 36 is connected to the gas introduction port 33a via a pipe 38. The gas supply 36 may include one or more gas sources, one or more flow rate controllers, and one or more on-off valves. Each of the one or more gas sources is connected to the gas introduction port 33a via a corresponding flow rate controller and a corresponding on-off valve. The gas supply 36 supplies various gases, such as process gases for use in a degassing process, an annealing process, and a film forming process, which will be described later.

The plasma processing apparatus 1 further includes an exhaust device 40. The exhaust device 40 includes a pressure controller, such as an automatic pressure control valve, and a vacuum pump, such as a turbo molecular pump or a dry pump. The exhaust device 40 is connected to an exhaust pipe 42. The exhaust pipe 42 is connected to the bottom wall 12b of the chamber 10 and is in communication with the internal space of the chamber 10. Alternatively, the exhaust pipe 42 may be connected to the sidewall of the chamber 10.

The plasma processing apparatus 1 further includes a radio-frequency power supply 44. The radio-frequency power supply 44 is connected to the upper electrode 30 via a matcher 46. The radio-frequency power supply 44 supplies power having a frequency of a VHF band or lower (300 MHz or less) to the upper electrode 30. For example, the radio-frequency power supply 44 supplies power having any frequency of 100 kHz to 13.56 MHz to the upper electrode 30. In the embodiment, the radio-frequency power supply 44 corresponds to a power supply of the present disclosure.

The radio-frequency power supply 44 is connected to the upper electrode 30 via the matcher 46. The matcher 46 includes a matching circuit that matches a load impedance of the radio-frequency power supply 44 to an output impedance of the radio-frequency power supply 44.

The plasma processing apparatus 1 further includes an impedance circuit 50. The lower electrode 18 of the substrate support 14 is grounded via a wiring 28a. The impedance circuit 50 is provided between the lower electrode 18 of the wiring 28a and the ground. An electrical path 51 through which the lower electrode 18 of the substrate support 14 is connected to the ground is formed by the wiring 28a via the impedance circuit 50. The electrical path 51 is constituted by the wiring 28a, which is electrically connected to the lower electrode 18, and the impedance circuit 50. In the embodiment, the electrical path 51 corresponds to a first electrical path of the present disclosure.

The impedance circuit 50 can provide a variable impedance between the lower electrode 18 and the ground. The impedance circuit 50 may include a series circuit or a parallel circuit of an inductor and a capacitor. The inductor may be a variable inductor, and the capacitor may be a variable capacitor.

The impedance of the impedance circuit 50 is set so that an impedance of the electrical path 51 becomes higher than an impedance of the electrical path 52. The impedance of the impedance circuit 50 can be set by the controller 80, which will be described later. Further, while the impedance of the impedance circuit 50 is set appropriately in advance, the impedance of the impedance circuit 50 may also be changed dynamically by the controller 80 during the film forming process on the substrate W.

The plasma processing apparatus 1 further includes the controller 80. The controller 80 is configured to control individual components of the plasma processing apparatus 1. The controller 80 may be a computer, which includes a processor, a computer-readable storage such as a memory, an input device, a display device, a signal input/output interface, and the like. A control program and recipe data are stored in the storage of the controller 80. The processor of the controller 80 executes the control program to control individual components of the plasma processing apparatus 1 according to the recipe data. A film forming method according to the embodiment is executed in the plasma processing apparatus 1 by controlling individual components of the plasma processing apparatus 1 by the controller 80.

Next, a flow will be briefly described in which the plasma processing apparatus 1 according to the embodiment performs film formation on the loaded substrate W under control of the controller 80.

When loading the substrate W into the plasma processing apparatus 1, the controller 80 controls the lifting mechanism 26 to lower the substrate support 14 to the transfer position. The substrate W is placed on the substrate support 14 by a transfer mechanism such as a transfer arm (not shown). When performing film formation on the substrate W, the controller 80 controls the lifting mechanism 26 to raise the substrate support 14. The controller 80 controls the exhaust device 40 to depressurize an interior of the chamber 10 by the exhaust device 40. The controller 80 controls the gas supply 36 to supply various gases for use in film formation from the gas supply 36 and introduce a process gas into the chamber 10 from the upper electrode 30. Further, the controller 80 controls the radio-frequency power supply 44 to supply power having a frequency of the VHF band or lower from the radio-frequency power supply 44 to the upper electrode 30, thereby generating plasma in the chamber 10 and performing film formation on the substrate W.

The impedance of the impedance circuit 50 is set so that the impedance of the electrical path 51 becomes higher than the impedance of the electrical path 52. For example, the impedance of the impedance circuit 50 is set so that the impedance of the electrical path 51 becomes at least 10 times higher than the impedance of the electrical path 52. For example, in the electrical path 52, although the ring electrode 70 is a conductor and thus has a low electrical resistance, plasma sheath generated around the ring electrode 70 has an impedance of about several hundred ohms. For this reason, the impedance of the impedance circuit 50 is set so that the impedance of the electrical path 51 becomes several kilo-ohms or more.

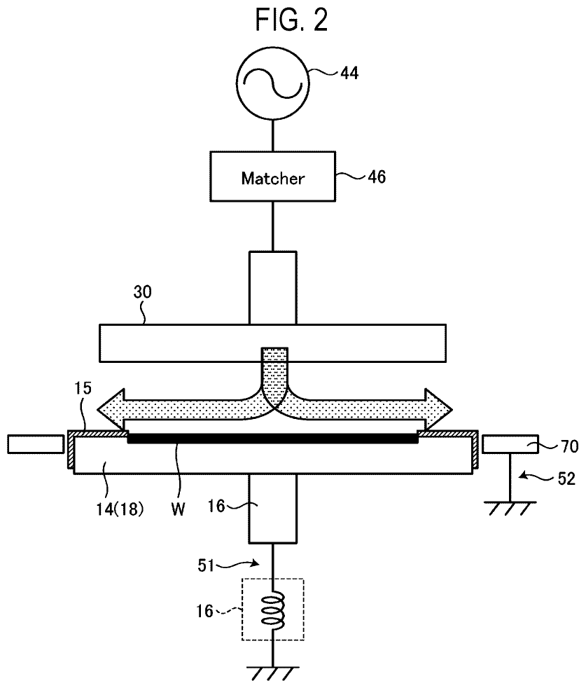

FIG. 2 is a diagram schematically illustrating an example of a flow of power according to an embodiment. FIG. 2 schematically shows a configuration inside the chamber 10. In FIG. 2, a case in which the substrate support 14 is formed of a conductive metal and the entire substrate support 14 functions as the lower electrode 18 is shown. A covering 15 is provided on the substrate support 14. The covering 15 covers a peripheral edge portion and a side surface of the substrate support 14. The covering 15 is formed of, for example, alumina.

Power supplied from the upper electrode 30 flows to the ground from the substrate support 14 (the lower electrode 18) via the electrical path 51, and also flows to the ground from the ring electrode 70 via the electrical path 52. The impedance of the electrical path 51 is set to be higher than the impedance of the electrical path 52. For example, the impedance of the electrical path 51 is at least 10 times higher than the impedance of the electrical path 52. As a result, electrical coupling between the upper electrode 30 and the lower electrode 18 is weakened, and most of the power supplied from the upper electrode 30 flows to the ground from the ring electrode 70 via the electrical path 52. Therefore, a current flowing to the lower electrode 18 is reduced, and ion energy imparted to the substrate W on the substrate support 14 is reduced.

Next, a first experiment for measuring an ion energy distribution in the plasma processing apparatus 1 will be described. The first experiment described below does not limit the present disclosure.

### First Experiment

In the first experiment, ion energy distributions in plasma were measured using the plasma processing apparatus 1 without the ring electrode 70 and the plasma processing apparatus 1 with the ring electrode 70. In the first experiment, the ion energy distributions in the plasma were measured by varying the power supplied from the radio-frequency power supply 44 to 100 W, 200 W, 300 W, 500 W, and 800 W. In the plasma processing apparatus 1 with the ring electrode 70, the ion energy distributions were measured in a state in which the impedance of the electrical path 51 is at least 10 times higher than the impedance of the electrical path 52. Other conditions for the first experiment are described below.

### Conditions of First Experiment

Gas supplied into the chamber 10: mixed gas of Ar gas and H₂ gas
Frequency of power supplied from the radio-frequency power supply 44: 450 kHz
Pressure inside the chamber 10: 500 mTorr (66.7 Pa)
Temperature of the substrate W: less than 60 degrees C.
Distance between the upper surface of the substrate support 14 and the lower surface of the upper electrode 30: 13.5 mm

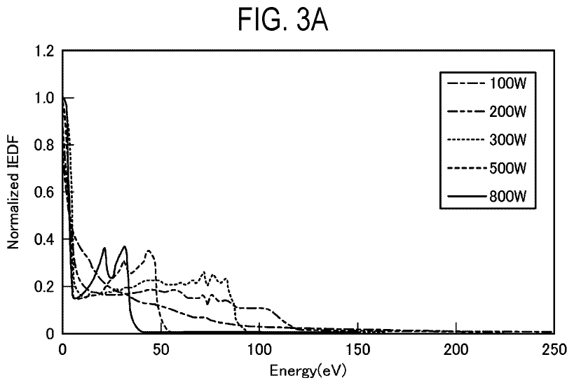

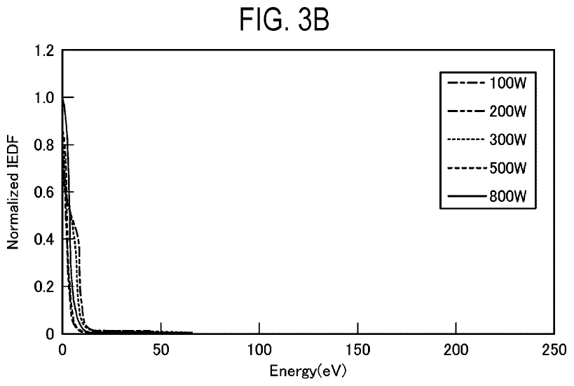

An example of a result of obtaining the ion energy distributions will be described. FIGS. 3A and 3B are diagrams illustrating the ion energy distributions in the first experiment. FIG. 3A illustrates the ion energy distributions measured by the plasma processing apparatus 1 without the ring electrode 70. FIG. 3B illustrates the ion energy distributions measured by the plasma processing apparatus 1 with the ring electrode 70. As shown in FIG. 3A, in the plasma processing apparatus 1 without the ring electrode 70, ions with ion energy of 40 eV or more were generated in plasma. On the other hand, as shown in FIG. 3B, in the plasma processing apparatus 1 with the ring electrode 70, ion energy of ions contained in the plasma could be reduced to be less than 10 eV. For graphene film formation, it is necessary to suppress ion energy of plasma to a low level. Therefore, the plasma processing apparatus 1 with the ring electrode 70, as in the embodiment, can be used for graphene film formation.

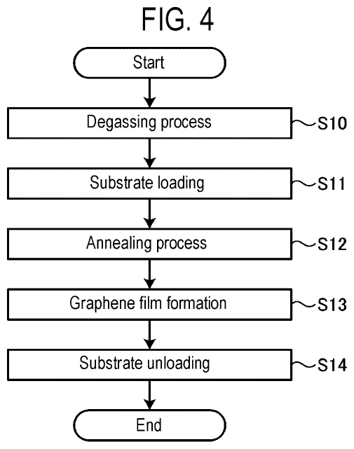

Next, a film forming method of forming graphene on the substrate W by the plasma processing apparatus 1 according to an embodiment will be described. FIG. 4 is a flowchart showing an example of the film forming method according to an embodiment.

A degassing process of removing residual oxygen inside the chamber 10 is performed (step S10). The degassing process is performed before the substrate W is placed on the substrate support 14. In the degassing process, a distance between the upper surface of the substrate support 14 and the lower surface of the upper electrode 30 may be set to be equal to or longer than that in an annealing process described later. In the degassing process, specifically, the distance between the upper surface of substrate support 14 and the lower surface of upper electrode 30 may be 80 mm to 130 mm. The pressure inside the chamber 10 during the degassing process may be 100 mTorr to 500 mTorr (13.3 Pa to 66.66 Pa). In the degassing process, a process gas including an inert gas is supplied into the chamber 10 to generate plasma, and the interior of chamber 10 is exposed to the plasma to remove residual oxygen inside the chamber 10. Examples of the inert gas included in the process gas for the degassing process include N₂ gas and Ar gas. The process gas for the degassing process includes at least one of N₂ gas or Ar gas. For example, the controller 80 controls the lifting mechanism 26 to raise the substrate support 14 to a position at which the upper surface of the substrate support 14 is distanced 80 mm to 130 mm from the lower surface of the upper electrode 30. The controller 80 controls the exhaust device 40 to depressurize the interior of the chamber 10 to 100 mTorr to 500 mTorr (13.3 Pa to 66.66 Pa) by the exhaust device 40. The controller 80 controls the gas supply 36 to supply the process gas including the inert gas from the gas supply 36 and to introduce the process gas into the chamber 10 from the upper electrode 30. Further, the controller 80 controls the radio-frequency power supply 44 to supply power having a frequency of a VHF band or lower to the upper electrode 30 from the radio-frequency power supply 44, thereby generating plasma in the chamber 10 and removing residual oxygen inside the chamber 10. The frequency of the power supplied from the radio-frequency power supply 44 may be the same as that used in a film forming process described later. In the embodiment, step S10 corresponds to a process d) of the present disclosure. The degassing process may also be omitted.

Subsequently, the substrate W as a target for film formation is loaded (step S11). For example, the controller 80 controls the lifting mechanism 26 to lower the substrate support 14 to the transfer position. The substrate W is placed on the substrate support 14 by a transfer mechanism such as a transfer arm (not shown). The substrate W may have, on a surface thereof, a metal-containing film on which graphene can be formed. The metal-containing film is any one of a film of Ru, Co, Cu, W, or Mo, an oxide film thereof, a nitride film thereof, an oxynitride film thereof, a silicon film, a silicon-containing oxide film, a silicon-containing nitride film, and a silicon-containing oxynitride film. The metal-containing film may be formed on the substrate W before graphene film formation in the plasma processing apparatus 1. In the embodiment, step S11 corresponds to a process a) of the present disclosure.

Subsequently, an annealing process of the substrate W is performed (step S12). The annealing process is performed as a pre-process of a film forming process described later, in order to remove metal oxides from the metal-containing film on the surface of the substrate W. In the annealing process, the distance between the upper surface of the substrate support 14 and the lower surface of the upper electrode 30 may be set to be equal to or shorter than that in the above-described degassing process. Specifically, the distance between the upper surface of the substrate support 14 and the lower surface of the upper electrode 30 may be 80 mm to 130 mm in the annealing process. The pressure inside the chamber 10 during the annealing process may be 50 mTorr to 2,000 mTorr (6.7 Pa to 266.4 Pa). In the annealing process, the metal oxides are removed from the metal-containing film by exposing the surface of the substrate W on which the metal-containing film is formed to a process gas including a reducing gas. The reducing gas included in the process gas for the annealing process includes, for example, hydrogen gas, CO gas, and a hydrocarbon gas. The process gas for the annealing process includes at least one of hydrogen gas, CO gas, or the hydrocarbon gas. The process gas for the annealing process may further include an inert gas. The inert gas included in the process gas for the annealing process includes, for example, Ar gas, He gas, N₂ gas, and Kr gas. The process gas for the annealing process may include at least one of Ar gas, He gas, N₂ gas, or Kr gas. For example, the controller 80 controls the lifting mechanism 26 to raise the substrate support 14 to a position at which the upper surface of the substrate support 14 is distanced from the lower surface of the substrate support 14 by the same distance as in the degassing process or a distance from the lower surface of the substrate support 14 becomes shorter than that in the degassing process. The controller 80 controls the exhaust device 40 to depressurize the interior of the chamber 10 to 50 mTorr to 2,000 mTorr (6.7 Pa to 266.4 Pa) by the exhaust device 40. The controller 80 controls the gas supply 36 to supply the process gas including the reducing gas from the gas supply 36 and to introduce the process gas into the chamber 10 from the upper electrode 30. Further, in the annealing process, a first annealing process in which the surface of the substrate W on which the metal-containing film is formed is exposed to the reducing gas and the inert gas, and a second annealing process in which the surface of the substrate W on which the metal-containing film is formed is exposed to the inert gas after the first annealing process may be performed. In the embodiment, step S12 corresponds to a process c) of the present disclosure. The annealing process may be omitted.

Subsequently, a film forming process for forming a graphene film on the substrate W is performed (step S13). In the film forming process, the distance between the upper surface of the substrate support 14 and the lower surface of the upper electrode 30 may be equal to or shorter than that in the above-described annealing process. In the film forming process, the distance between the upper surface of the substrate support 14 and the lower surface of the upper electrode 30 may be 10 mm to 80 mm, and more specifically 20 mm to 30 mm. In the film forming process, a process gas including a carbon-containing gas is supplied into the chamber 10 to generate plasma and form the graphene film on the metal-containing film of the substrate W. The carbon-containing gas includes, for example, a hydrocarbon-based gas. The hydrocarbon-based gas includes, for example, CₓH_{y} (where x and y are integers of one or more) gas such as C₂H₂ gas, CH₄ gas, or C₂H₄ gas. The process gas for the film forming process includes at least one CₓH_{y} (where x and y are integers of one or more) gases such as C₂H₂ gas, CH₄ gas, and C₂H₄ gas. The process gas may include an inert gas. Examples of the inert gas include Ar gas, He gas, N₂ gas, and Kr gas. The process gas for the film forming process may include at least one of Ar gas, He gas, N₂ gas, or Kr gas. The temperature of the substrate W in the film forming process may be 300 degrees C. to 500 degrees C. The pressure inside the chamber 10 in the film forming process may be 200 mTorr to 600 mTorr (26.7 Pa to 80 Pa). The power for use in the film forming process may be 50 W to 1,000 W. The frequency of the power for use in the film forming process may be a frequency equal to or lower than the VHF band, and may be 100 kHz to 13.56 MHz. For example, the controller 80 controls the lifting mechanism 26 to raise the substrate support 14 to a predetermined processing position at which the upper surface of the substrate support 14 is distanced 10 mm to 80 mm from the lower surface of the substrate support 14. The placement position of the ring electrode 70 is adjusted so that the upper surface of the substrate support 14 raised to the processing position is at the same height as the upper surface of the ring electrode 70. The ring electrode 70 surrounds a periphery of the substrate support 14 at the processing position. The controller 80 controls the heater power supply 22 to heat the substrate W by the heater 20 to a temperature of 300 degrees C. to 500 degrees C. The controller 80 may start adjusting the temperature of the substrate W during the annealing process to a film formation temperature. The controller 80 controls the exhaust device 40 to depressurize the interior of the chamber 10 to 200 mTorr to 600 mTorr (26.7 Pa to 80 Pa) by the exhaust device 40. The controller 80 controls the gas supply 36 to supply the process gas including the carbon-containing gas from the gas supply 36 and introduce the process gas into the chamber 10 from the upper electrode 30. Further, the controller 80 controls the radio-frequency power supply 44 to supply power having a frequency of the VHF band or lower from the radio-frequency power supply 44 to the upper electrode 30, thereby generating plasma in the chamber 10 and forming the graphene film on the metal-containing film of the substrate W. In the embodiment, step S13 corresponds to a process b) of the present disclosure.

Subsequently, the substrate W on which the graphene film has been formed is unloaded (step S14). For example, the controller 80 controls the lifting mechanism 26 to lower the substrate support 14 to the transfer position. The substrate W is taken out and unloaded from the substrate support 14 by a transfer mechanism such as a transfer arm (not shown).

Next, a second experiment and a third experiment in which graphene is formed on the substrate W by the plasma processing apparatus 1 according to the embodiment will be described. The second and third experiments described below do not limit the present disclosure.

### Second Experiment

In the second experiment, graphene was formed on the substrate W by the film forming method shown in FIG. 4. In the second experiment, graphene was formed on the substrate W having a surface on which a Co film was formed as a metal-containing film. Common processing conditions for the degassing process (step S10), the annealing process (step S12), and the film forming process (step S13) will be described below.

### Common Processing Conditions of Second Experiment

Frequency of the power supplied from the radio-frequency power supply 44: 450 kHz
Temperature of the substrate W: 400 degrees C.

Processing conditions specified for the degassing process, the annealing process, and the film forming process, respectively, will be described below. Gas flow rates for the degassing process, the annealing process, and the film forming process were set for an appropriate flow.

### Processing Conditions for Degassing Process of Second Experiment

Gas supplied into the chamber 10: N₂ gas
Power supplied from the radio-frequency power supply 44: 300 W
Pressure inside the chamber 10: 300 mTorr (40.0 Pa)
Distance between the upper surface of the substrate support 14 and the lower surface of the upper electrode 30: 80 mm
Processing time: 10 minutes

### Processing Conditions for Annealing Process of Second Experiment

Gas supplied into the chamber 10: H₂ gas
Power supplied from the radio-frequency power supply 44: 0 W (plasmaless)
Pressure inside the chamber 10: 50 mTorr (6.7 Pa)
Distance between the upper surface of the substrate support 14 and the lower surface of the upper electrode 30: 80 mm
Processing time: 10 minutes

### Processing Condition for Film Forming Process of Second Experiment

Gas supplied into the chamber 10: mixed gas of C₂H₂ gas, H₂ gas, and Ar gas
Power supplied from the radio-frequency power supply 44: 300 W
Pressure inside the chamber 10: 500 mTorr (66.7 Pa)
Distance between the upper surface of the substrate support 14 and the lower surface of the upper electrode 30: 20 mm
Processing time: 1 minutes

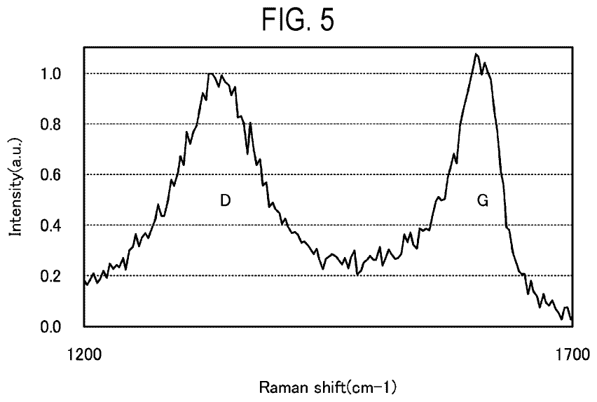

In the second experiment, CoOₓ was removed from the Co film on the surface of substrate W by the annealing process, and graphene was formed on the Co film of substrate W by the film forming process. In the second experiment, a Raman spectrum of the substrate W on which graphene was formed was measured. FIG. 5 is a diagram illustrating the Raman spectrum of the substrate W on which graphene was formed in the second experiment. The horizontal axis in FIG. 5 represents an amount of wavelength shift (Raman shift (cm⁻¹)) from an excitation wavelength. The vertical axis represents a signal intensity of each wavelength normalized such that a predetermined signal intensity is defined as 1. In the Raman spectrum shown in FIG. 5, a G peak and a D peak were observed. From this, it can be confirmed that the graphene film has been formed on the substrate W.

### Third Experiment

In the third experiment, graphene was formed on the substrate W by the film forming method shown in FIG. 4. In the third experiment, graphene was formed on the substrate W on which a Ru film as a metal-containing film was formed on the surface of the substrate W. In the third experiment, a second annealing process was performed after a first annealing process in the annealing process (step S12). Common processing conditions for the degassing process (step S10), the first annealing process (step S12), the second annealing process (step S12), and the film forming process (step S13) will be described below.

### Common Processing Conditions of Third Experiment

Frequency of the power supplied from the radio-frequency power supply 44: 450 kHz
Temperature of the substrate W: 400 degrees C.

Processing conditions for the degassing process, the annealing process, and the film forming process, respectively, will be described below. Gas flow rates for the degassing process, the annealing process, and the film forming process were set for an appropriate flow.

### Processing Conditions for Degassing Process of Third Experiment

Gas supplied into the chamber 10: N₂ gas
Power supplied from the radio-frequency power supply 44: 300 W
Pressure inside the chamber 10: 300 mTorr (40.0 Pa)
Distance between the upper surface of the substrate support 14 and the lower surface of the upper electrode 30: 130 mm
Processing time: 10 minutes

### Processing Conditions for First Annealing Process of Third Experiment

Gas supplied into the chamber 10: mixed gas of H₂ gas and Ar gas
Power supplied from the radio-frequency power supply 44: 0 W (plasmaless)
Pressure inside the chamber 10: 400 mTorr (53.2 Pa)
Distance between the upper surface of the substrate support 14 and the lower surface of the upper electrode 30: 90 mm
Processing time: 1 minute

### Processing Conditions for Second Annealing Process of Third Experiment

Gas supplied into chamber 10: Ar gas
Power supplied from radio-frequency power supply 44: 0 W (plasmaless)
Pressure inside chamber 10: 2,000 mTorr (266.6 Pa)
Distance between upper surface of substrate support 14 and lower surface of upper electrode 30: 90 mm
Processing time: 10 min

### Processing Conditions for Film Forming Process of Third Experiment

Gas supplied into chamber 10: mixed gas of C₂H₂ gas, H₂ gas, and Ar gas
Power supplied from radio-frequency power supply 44: 300 W
Pressure inside chamber 10: 300 mTorr (40.0 Pa)
Distance between upper surface of substrate support 14 and lower surface of upper electrode 30: 60 mm
Processing time: 1 min

In the third experiment, RuOₓ was removed from the Ru film on the surface of the substrate W by the first annealing process and the second annealing process, and graphene was formed on the Ru film of the substrate W by the film forming process. As a result of measuring the Raman spectrum of the substrate W on which graphene was formed in the third experiment, a peak G and a peak D were observed in the Raman spectrum. From this, it can be confirmed that the graphene film has been formed on the substrate W.

In addition, as a result of forming the graphene on the substrate W by changing the frequency of the power supplied from the radio-frequency power supply 44, the graphene film can be formed on the substrate W when the frequency is 100 kHz to 13.56 MHz. Further, as a result of forming the graphene on the substrate W by changing the distance between the upper surface of the substrate support 14 and the lower surface of the upper electrode 30, the graphene film can be formed on the substrate W when the distance is 10 mm to 80 mm. However, when the distance between the upper surface of the substrate support 14 and the lower surface of the upper electrode 30 is set to be short, carbon nanowalls (CNWs) are formed in the graphene film. When forming a graphene film having good continuity, the distance between the upper surface of the substrate support 14 and the lower surface of the upper electrode 30 may be 30 mm to 60 mm.

Here, in conventional graphene film formation by microwaves, graphene cannot be formed unless a chamber is depressurized to a low pressure of about 20 mTorr to 80 mTorr (2.7 Pa to 10.7 Pa).

In contrast, the plasma processing apparatus 1 according to the embodiment can form graphene even at a high pressure of, for example, 500 mTorr (66.7 Pa), as shown in the processing conditions for the film forming process of the second experiment described above. Consequently, the plasma processing apparatus 1 does not require a use of a turbo molecular pump in the exhaust device 40. Further, when improvement in productivity of graphene deposition is taken into account, the configuration of the present disclosure can be applied to the film forming apparatus of a multi-wafer type. Furthermore, since graphene can be formed with a short gap, a volume of a chamber can be reduced, and a use amount of a film formation gas can also be reduced.

In the embodiment described above, the case in which the electrical path 52 from the ring electrode 70 to the ground is used as a conductive path from the ring electrode 70 to the ground via the chamber body 12 and the wiring 13 has been described by way of example. However, the technique of the present disclosure is not limited thereto. For example, the electrical path 52 may be any conductive path through which a current flows from the ring electrode 70 to the ground. For example, the ring electrode 70 may be electrically insulated from the chamber body 12, and a grounded wiring may be connected to the ring electrode 70 so that the wiring serves as the electrical path 52. The electrical path 51 may also be any conductive path that extends from the lower electrode 18 of the substrate support 14 to the ground.

Hereinabove, the embodiment has been described. As described above, the film forming method of the embodiment includes the process a) (step S11) and the process b) (step S13). In the process a), the substrate W is placed on the substrate support 14 inside the chamber 10, in which the substrate support 14 configured to place the substrate W thereon and connected to the ground via the electrical path 51 is disposed, the conductive ring electrode 70 connected to the ground via the electrical path 52 is disposed around the substrate support 14, and the upper electrode 30 is disposed to face the substrate support 14. In the process b), a process gas including a carbon-containing gas is supplied into the chamber 10, the impedance of the electrical path 51 is set to be higher than the impedance of the electrical path 52, and power having a frequency of the VHF band or lower is supplied to the upper electrode 30 to generate plasma inside the chamber 10 and form a graphene film on the substrate W. Accordingly, the film forming method of the embodiment can form graphene on the substrate W even by using plasma generated by power having a frequency of the VHF band or lower.

In the process b), the impedance of the electrical path 51 is at least 10 times higher than the impedance of the electrical path 52. As a result, most of the power supplied from the upper electrode 30 flows to the ground from the ring electrode 70 via the electrical path 52. Therefore, ion energy of ions contained in the plasma can be reduced significantly. Accordingly, the film forming method of the embodiment can form graphene on the substrate W even by the plasma generated by power having a frequency of the VHF band or lower.

In the process b), the distance between the upper surface of the substrate support 14 and the lower surface of the upper electrode 30 is 10 mm to 80 mm. In the process b), power having any frequency of 100 kHz to 13.56 MHz is supplied to the upper electrode 30. The carbon-containing gas is a hydrocarbon-based gas. The process gas includes an inert gas. The inert gas is at least one of Ar gas, He gas, N₂ gas, or Kr gas. The substrate support 14 is provided with a heater. In the process b), the temperature of the substrate W is adjusted to be 300 degrees C. to 500 degrees C. by the heater. In the process b), the pressure inside the chamber 10 is 200 mTorr to 600 mTorr. In the process b), the power supplied to the upper electrode 30 is 50 W to 1,000 W. The substrate W has, on surface thereof, a metal-containing film on which graphene can be formed. The metal-containing film is any of a film of Ru, Co, Cu, W, or Mo, an oxide film thereof, or a nitride film thereof. Accordingly, the film forming method of the embodiment can form graphene on the substrate W even by plasma generated by power having a frequency of the VHF band or lower.

The film forming method according to the embodiment further includes the process c) (step S12). In the process c), the surface of the metal-containing film is exposed to a second process gas including a reducing gas before the process b). In the process c), the distance between the upper surface of the substrate support 14 and the lower surface of the upper electrode 30 is 80 mm to 130 mm. In the process c), the pressure inside the chamber 10 is 50 mTorr to 2,000 mTorr. The reducing gas is at least one of hydrogen gas, CO gas, or a hydrocarbon gas. Therefore, the film forming method according to the embodiment can remove metal oxides from the metal-containing film on the surface of the substrate W.

In addition, the distance between the upper surface of the substrate support 14 and the lower surface of the upper electrode 30 is changeable. In the process c), the distance between the upper surface of the substrate support 14 and the lower surface of the upper electrode 30 is set to be equal to or longer than that in the process b). As a result, the film forming method according to the embodiment can remove the metal oxides from the metal-containing film on the surface of the substrate W.

In addition, the film forming method according to the embodiment further includes the process d) (step S10). In the process d), before the process a) and the process b), the power is supplied to the upper electrode 30, while a third process gas including an inert gas is supplied into the chamber 10, to remove residual oxygen inside the chamber 10. In the process d), the distance between the upper surface of the substrate support 14 and the lower surface of the upper electrode 30 is 80 mm to 130 mm. As a result, the film forming method according to the embodiment can remove residual oxygen inside the chamber 10 during graphene film formation.

According to the present disclosure in some embodiments, it is possible to form graphene on a substrate even by plasma generated by power having a frequency of a VHF band or lower.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

Regarding the above-described embodiments, supplementary notes will be also disclosed as follows.

### Supplementary Note 1

A film forming method, including:
a) placing a substrate on a stage inside a processing container, in which the stage configured to place the substrate on the stage and connected to a ground via a first electrical path is disposed, a conductive ring connected to the ground via a second electrical path is disposed around the stage, and an electrode is disposed to face the stage; and
b) forming graphene on the substrate by while supplying a first process gas including a carbon-containing gas into the processing container, setting an impedance of the first electrical path to be higher than an impedance of the second electrical path, and supplying power having a frequency of a very high frequency (VHF) band or lower to the electrode to generate plasma inside the processing container.

### Supplementary Note 2

The film forming method of Supplementary Note 1, wherein in b), the impedance of the first electrical path is set to be at least ten times higher than the impedance of the second electrical path.

### Supplementary Note 3

The film forming method of Supplementary Note 1 or 2, wherein in b), a distance between an upper surface of the stage and a lower surface of the electrode is 10 mm to 80 mm.

### Supplementary Note 4

The film forming method of any one of Supplementary Notes 1 to 3, wherein in b), power having any frequency of 100 kHz to 13.56 MHz is supplied to the electrode.

### Supplementary Note 5

The film forming method of any one of Supplementary Notes 1 to 4, wherein the carbon-containing gas is a hydrocarbon-based gas.

### Supplementary Note 6

The film forming method of any one of Supplementary Notes 1 to 5, wherein the first process gas includes an inert gas.

### Supplementary Note 7

The film forming method of Supplementary Note 6, wherein the inert gas is at least one of Ar gas, He gas, N₂ gas, or Kr gas.

### Supplementary Note 8

The film forming method of any one of Supplementary Notes 1 to 7, wherein the stage includes a heater, and
wherein in b), a temperature of the substrate is adjusted to be 300 degrees C. to 500 degrees C. by the heater.

### Supplementary Note 9

The film forming method of any one of Supplementary Notes 1 to 8, wherein in b), a pressure inside the processing container is 200 mTorr to 600 mTorr.

### Supplementary Note 10

The film forming method of any one of Supplementary Notes 1 to 9, wherein in b), wherein the power supplied to the electrode is 50 W to 1,000 W.

### Supplementary Note 11

The film forming method of any one of Supplementary Notes 1 to 10, wherein the substrate has a metal-containing film which is formed on a surface of the substrate, and on which the graphene is capable of being formed.

### Supplementary Note 12

The film forming method of Supplementary Note 11, wherein the metal-containing film is any one of a film of Ru, Co, Cu, W, or Mo, an oxide film of Ru, Co, Cu, W, or Mo, and a nitride film of Ru, Co, Cu, W, or Mo.

### Supplementary Note 13

The film forming method of Supplementary Note 11 or 12, further including, before b), c) exposing a surface of the metal-containing film to a second process gas including a reducing gas.

### Supplementary Note 14

The film forming method of Supplementary Note 13, wherein in c), a distance between an upper surface of the stage and a lower surface of the electrode is 80 mm to 130 mm.

### Supplementary Note 15

The film forming method of Supplementary Note 13 or 14, wherein in c), a pressure inside the processing container is 50 mTorr to 2,000 mTorr.

### Supplementary Note 16

The film forming method of any one of Supplementary Notes 11 to 15, wherein the reducing gas is at least one of hydrogen gas, CO gas, or a hydrocarbon gas.

### Supplementary Note 17

The film forming method of any one of Supplementary Notes 11 to 16, wherein a distance between an upper surface of the stage and a lower surface of the electrode is changeable, and
wherein in c), the distance between the upper surface of the stage and the lower surface of the electrode is set to be equal to or longer than that in b).

### Supplementary Note 18

The film forming method of any one of Supplementary Notes 1 to 17, further including, before a) and b), d) removing residual oxygen inside the processing container by supplying power to the electrode while supplying a third process gas including an inert gas into the processing container.

### Supplementary Note 19

The film forming method of Supplementary Note 18, wherein in d), a distance between an upper surface of the stage and a lower surface of the electrode is 80 mm to 130 mm.

### Supplementary Note 20

A plasma processing apparatus, including:
a processing container;
a stage disposed inside the processing container, configured to place a substrate on the stage, and connected to a ground via a first electrical path;
a conductive ring disposed around the stage and connected to the ground via a second electrical path;
an electrode configured disposed inside the processing container to face the stage;
a gas supply configured to supply a process gas into the processing container;
a power supply configured to supply power having a frequency of a very high frequency (VHF) band or lower to the electrode; and
a controller configured to perform a control to set an impedance of the first electrical path to be higher than an impedance of the second electrical path, and supply the power having the frequency of the VHF band or lower to the electrode from the power supply, while supplying a process gas including a carbon-containing gas into the processing container from the gas supply.

What is claimed is:

1. A film forming method, comprising:
a) placing a substrate on a stage inside a processing container, in which the stage configured to place the substrate on the stage and connected to a ground via a first electrical path is disposed, a conductive ring connected to the ground via a second electrical path is disposed around the stage, and an electrode is disposed to face the stage; and
b) forming graphene on the substrate by while supplying a first process gas including a carbon-containing gas into the processing container, setting an impedance of the first electrical path to be higher than an impedance of the second electrical path, and supplying power having a frequency of a very high frequency (VHF) band or lower to the electrode to generate plasma inside the processing container.

2. The film forming method of claim 1, wherein in b), the impedance of the first electrical path is set to be at least ten times higher than the impedance of the second electrical path.

3. The film forming method of claim 1, wherein in b), a distance between an upper surface of the stage and a lower surface of the electrode is 10 mm to 80 mm.

4. The film forming method of claim 1, wherein in b), power having any frequency of 100 kHz to 13.56 MHz is supplied to the electrode.

5. The film forming method of claim 1, wherein the carbon-containing gas is a hydrocarbon-based gas.

6. The film forming method of claim 1, wherein the first process gas includes an inert gas.

7. The film forming method of claim 6, wherein the inert gas is at least one of Ar gas, He gas, N₂ gas, or Kr gas.

8. The film forming method of claim 1, wherein the stage includes a heater, and
wherein in b), a temperature of the substrate is adjusted to be 300 degrees C. to 500 degrees C. by the heater.

9. The film forming method of claim 1, wherein in b), a pressure inside the processing container is 200 mTorr to 600 mTorr.

10. The film forming method of claim 1, wherein in b), wherein the power supplied to the electrode is 50 W to 1,000 W.

11. The film forming method of claim 1, wherein the substrate has a metal-containing film which is formed on a surface of the substrate, and on which the graphene is capable of being formed.

12. The film forming method of claim 11, wherein the metal-containing film is any one of a film of Ru, Co, Cu, W, or Mo, an oxide film of Ru, Co, Cu, W, or Mo, and a nitride film of Ru, Co, Cu, W, or Mo.

13. The film forming method of claim 11, further comprising, before b), c) exposing a surface of the metal-containing film to a second process gas including a reducing gas.

14. The film forming method of claim 13, wherein in c), a distance between an upper surface of the stage and a lower surface of the electrode is 80 mm to 130 mm.

15. The film forming method of claim 13, wherein in c), a pressure inside the processing container is 50 mTorr to 2,000 mTorr.

16. The film forming method of claim 13, wherein the reducing gas is at least one of hydrogen gas, CO gas, or a hydrocarbon gas.

17. The film forming method of claim 13, wherein a distance between an upper surface of the stage and a lower surface of the electrode is changeable, and
wherein in c), the distance between the upper surface of the stage and the lower surface of the electrode is set to be equal to or longer than that in b).

18. The film forming method of claim 1, further comprising, before a) and b), d) removing residual oxygen inside the processing container by supplying power to the electrode while supplying a third process gas including an inert gas into the processing container.

19. The film forming method of claim 18, wherein in d), a distance between an upper surface of the stage and a lower surface of the electrode is 80 mm to 130 mm.

20. A plasma processing apparatus, comprising:
a processing container;
a stage disposed inside the processing container, configured to place a substrate on the stage, and connected to a ground via a first electrical path;
a conductive ring disposed around the stage and connected to the ground via a second electrical path;
an electrode configured disposed inside the processing container to face the stage;
a gas supply configured to supply a process gas into the processing container;
a power supply configured to supply power having a frequency of a very high frequency (VHF) band or lower to the electrode; and
a controller configured to perform a control to set an impedance of the first electrical path to be higher than an impedance of the second electrical path, and supply the power having the frequency of the VHF band or lower to the electrode from the power supply, while supplying a process gas including a carbon-containing gas into the processing container from the gas supply.
